(19) United States
(12) Patent Application Publication
(10) Pub. No.: US 2024/0194576 A1
(43) Pub. Date: Jun. 13, 2024

(54) POWER MODULE FOR A VEHICLE

(71) Applicant: Robert Bosch GmbH, Stuttgart (DE)

(72) Inventors: Juergen Zipprich, KUSTERDINGEN (DE); Daniel Feil, TROCHTELFINGEN (DE); Erik Sueske, REUTLINGEN (DE); Gunnar Bruns, Neumuenster (DE); Irfan Aydogmus, Nuertingen (DE); Sebastian Rock, TUEBINGEN (DE)

(21) Appl. No.: 18/531,070

(22) Filed: Dec. 6, 2023

(30) Foreign Application Priority Data
Dec. 12, 2022 (DE) 10 2022 213 481.8

(51) Int. Cl. H01L 23/498; H01L 23/00; H01L 23/373

(52) U.S. Cl. CPC H01L 23/49833; H01L 23/3735; H01L 24/32; H01L 24/33; H01L 24/48; H01L 24/83; H01L 24/92; H01L 2224/32225; H01L 2224/33181; H01L 2224/48091; H01L 2224/48225; H01L 2224/83201; H01L 2224/8384; H01L 2224/92147

(57) ABSTRACT

A power module for a vehicle. The power module includes a first circuit carrier having on a first side, a power conductor structure arranged on an electrically insulating layer; and a further circuit carrier arranged spatially parallel to the first circuit carrier having, on a first side, a further power conductor structure arranged on an electrically insulating layer, and, on a second side, a control signal conductor structure arranged on the electrically insulating layer; and at least one semiconductor switch having a semiconductor substrate with two power terminals and a control terminal. The two power terminals and a spacer element are arranged between the power conductor structure and the further power conductor structure in a stack with at least three sinter layers. The control terminal of the semiconductor switch is electrically connected via a connection line to a corresponding contact region of the control signal conductor structure.

### FIELD

The present invention relates to a power module for a vehicle. The present invention also relates to a method for constructing such a power module for a vehicle.

### BACKGROUND INFORMATION

German Patent Application No. DE 10 2015 223 602 A1 describes a power module for an electric motor. The power module has at least one semiconductor switch half bridge. In this case, the semiconductor switch half bridge has a high-side semiconductor switch and a low-side semiconductor switch. The semiconductor switches of the half bridge each have switching-path terminals formed by an in particular flat surface region of the semiconductor switch. The switching-path terminals, in particular a normal vector of the switching-path terminal, each point in the same direction. The high-side semiconductor switch and the low-side semiconductor switch enclose at least one electrically conductive layer between one another, which layer electrically connects a switching-path terminal of the low-side semiconductor switch and a switching-path terminal of the high-side semiconductor switch of the half bridge to one another. An output terminal of the half bridge is preferably formed by at least one electrically conductive layer.

### SUMMARY

A power module for a vehicle with the features of the present invention may have the advantage that a simple and cost-effective contacting of at least one control terminal of at least one semiconductor switch is made possible. A stack which comprises the at least one semiconductor switch, at least one spacer element and at least three sinter layers enables good heat dissipation. By means of the at least one spacer element, the heat capacity that can be absorbed in the event of a short circuit can be increased and the at least one semiconductor can be better protected.

Example embodiments of the present invention provide a power module for a vehicle, comprising a first circuit carrier, which has, on a first side, at least one power conductor structure arranged on an electrically insulating layer; and at least one further circuit carrier, which is arranged spatially parallel to the first circuit carrier and has, on a first side facing the first side of the first circuit carrier, at least one further power conductor structure arranged on an electrically insulating layer, and, on a second side facing away from the first side of the first circuit carrier, at least one control signal conductor structure arranged on the electrically insulating layer; and at least one semiconductor switch, which has a semiconductor substrate with two power terminals and at least one control terminal. The two power terminals of the at least one semiconductor switch and at least one spacer element are arranged between the at least one power conductor structure of the first circuit carrier and the at least one further power conductor structure of the at least one further circuit carrier in a stack with at least three sinter layers. In this case, the at least one control terminal of the semiconductor switch is electrically connected via a connection line to a corresponding contact region of the at least one control signal conductor structure. The connection line is arranged in a free space and overlaps portions of the stack and the at least one further circuit carrier.

In addition, a method for constructing such a power module for a vehicle is provided according to the present invention. In one example embodiment, in order to form a stack with at least three sinter layers, at least one semiconductor switch, which has a semiconductor substrate with two power terminals and at least one control terminal, is placed between at least one power conductor structure of a first circuit carrier and at least one further power conductor structure of at least one further circuit carrier onto the at least one power conductor structure of the first circuit carrier and is connected to the at least one power conductor structure of the first circuit carrier in a first sintering process. At least one spacer element is placed onto the at least one semiconductor switch and is connected to the at least one semiconductor switch in at least one further sintering process. The at least one further circuit carrier is placed onto the at least one spacer element and is connected to the at least one spacer element via a further sintering process. At least one connection line is thus arranged in a free space and is electrically connected to at least one control terminal of the semiconductor switch and to a corresponding contact region of at least one control signal conductor structure of the at least one further circuit carrier such that portions of the stack and the at least one further circuit carrier are overlapped by the at least one connection line.

According to an example embodiment of the present invention, the first circuit carrier and/or the at least one further circuit carrier can, for example, be designed as an AMB substrate (AMB: active metal braze) or as a DBC substrate (DBC: direct bonded copper). Preferably, the first circuit carrier can be designed as an AMB substrate and the at least one second circuit carrier can be designed as a DBC substrate. The semiconductor switches can preferably be designed as field-effect transistors so that drain terminals of the semiconductor switches can each correspond to a first power terminal and source terminals of the semiconductor switches can each correspond to a second power terminal. A control terminal can be understood to mean, for example, a gate terminal or a Kelvin source terminal of a field-effect transistor. In this case, the power terminals of the semiconductor switches are designed as contact surfaces.

As a result of the measures and developments disclosed herein according to the present invention, advantageous improvements of the power module, for a vehicle and of the method, and for constructing a power module for a vehicle, are possible.

According to an example embodiment of the present invention, it is particularly advantageous that the at least one further circuit carrier can be arranged at an offset from the at least one spacer element so that the free space for the connection line is formed. As a result, a sufficiently large free space for a tool can advantageously be provided, with which the at least one connection line can be electrically connected to at least one control terminal of the semiconductor switch and to the corresponding contact region of the at least one control signal conductor structure of the at least one further circuit carrier.

In an advantageous embodiment of the power module of the present invention, a first sinter layer can be formed between the at least one power conductor structure of the first circuit carrier and one of the two power terminals of the at least one semiconductor switch. A second sinter layer can be formed between the other of the two power terminals of the at least one semiconductor switch and the at least one spacer element. A third sinter layer can be formed between the at least one spacer element and the at least one further power conductor structure of the at least one further circuit carrier. In this case, at least one of the sinter layers can be applied as a sintering paste to the corresponding contact region or power terminal. Preferably, the first sinter layer and the third sinter layer can each be applied as a sintering paste. In order to enable good heat transfer between the corresponding power terminal of the at least one semiconductor switch and the at least one spacer and to increase the free space, the second sinter layer can preferably be applied as a sinter foil to the corresponding power terminal. By using the sinter foil, the dimensions of the resulting sinter layer can be adapted to the dimensions of the surface of the corresponding power terminal of the at least one semiconductor switch, without the sinter layer protruding beyond the at least one spacer and projecting into the free space to be provided for the at least one connection line. Since the use of sintering paste is substantially more cost-effective than the use of sinter foil, an attempt is made to implement as many sinter layers of the power module as possible by means of sintering paste.

In a further advantageous embodiment of the power module of the present invention, a first contact region of the at least one power conductor structure of the first circuit carrier can correspond to at least one surface of the corresponding power terminal of the at least one semiconductor switch. Since the dimensions of the resulting first sinter layer between the at least one power conductor structure of the first circuit carrier and the corresponding power terminal of the at least one semiconductor switch is not critical for the free space, the resulting sinter layer can protrude beyond the corresponding power terminal.

In a further advantageous embodiment of the power module of the present invention, a first contact region of the at least one spacer element can correspond to a surface of the corresponding power terminal of the at least one semiconductor switch. Since the dimensions of the resulting second sinter layer between the corresponding power terminal of the at least one semiconductor switch and the at least one spacer element are critical for the free space, the resulting sinter layer should terminate, as possible, with the spacer element and not protrude beyond the spacer element into the free space.

In a further advantageous embodiment of the power module of the present invention, a first contact region of the at least one further power conductor structure of the at least one further circuit carrier can at least partially cover a second contact region of the at least one spacer element. The first contact region of the at least one further power conductor structure of the at least one further circuit carrier can cover 20% to 80% of the second contact region of the at least one spacer element. In this case, the covering can be designed depending on the current load to be carried and the free space to be provided.

It is particularly advantageous that, on a second side, the first circuit carrier has at least one thermal interface, which can be contacted with a cooling device. Thus, on the second side, preferably an underside, of the first circuit carrier, a heat sink, a water cooler, or another suitable cooling element can be connected via the thermal interface to the first circuit carrier. The thermally well conductive contacting can be produced, for example, via a solder connection or an adhesive connection with a conductive adhesive.

In a further advantageous embodiment of the power module of the present invention, the first circuit carrier can have, on a second side, preferably an underside, at least one conductor structure, which can form at least one thermal interface that can be contacted with a cooling device. Thus, on the second side of the first circuit carrier, a heat sink, a water cooler, or another suitable cooling element can, for example, be connected as a cooling device to the first circuit carrier via the thermal interface. The thermally well conductive contacting can be produced, for example, via a solder connection or an adhesive connection with a conductive adhesive.

In a further advantageous embodiment of the power module of the present invention, a casing can completely surround the power module while leaving the at least one thermal interface exposed. In this case, the casing can have at least one recess in the region of at least one external contact terminal. As a result of the casing, which can preferably be formed by a cured mold compound, the service life of the semiconductor switches and of the electrical connections and contactings can be significantly increased since the casing ensures good fixing of the semiconductor switches and of the at least one second circuit carrier even at high temperatures. In addition, the semiconductor switches and the various electrical contactings and connections and the conductor structures are protected from external influences by the casing. Furthermore, the casing allows easier handling of the encased power module so that the power modules can easily be further processed and transported.

In an advantageous embodiment of the method of the present invention, a sinter layer between the at least one spacer element and the at least one further power conductor structure of the at least one further circuit carrier can be applied as a sintering paste only to a portion of a contact region of the at least one spacer element for the third sintering process. In this case, the at least one further circuit carrier can be placed at such an offset from the at least one spacer element that an undercut is formed between the at least one spacer element and the at least one further power conductor structure of the at least one further circuit carrier. It is thereby possible to prevent an excessive amount of sintering paste from being applied to the contact region. Furthermore, the at least one further circuit carrier can be pressed onto the sintering paste with a specified force in the range of 1.5 g/mm² to 2.5 g/mm² so that the corresponding sinter layer can fill up the undercut before the third sintering process, without protruding beyond the corresponding power conductor structure of the at least one further circuit carrier into the free space to be provided.

Exemplary embodiments of the present invention are illustrated in the figures and explained in more detail in the following description. In the figures, identical reference signs denote components or elements which perform the same or analogous functions.

### BRIEF DESCRIPTION OF THE DRAWINGS

FIG. 1 shows a schematic partial sectional view of an exemplary embodiment of a power module according to the present invention for a vehicle after a second circuit carrier has been placed.

FIG. 2 shows a schematic partial sectional view of the power module according to the present invention for a vehicle of FIG. 1 after a third sintering process.

FIG. 3 shows a schematic partial sectional view of the power module according to the present invention for a vehicle of FIGS. 1 and 2 during the electrical contacting of at least one connection line.

FIG. 4 shows a schematic partial sectional view of the finished power module according to the present invention for a vehicle of FIGS. 1 to 3.

FIG. 5 shows a schematic flow chart of an exemplary embodiment of a method according to the present invention for constructing a power module for a vehicle of FIGS. 1 to 4.

### DETAILED DESCRIPTION OF EXAMPLE EMBODIMENTS

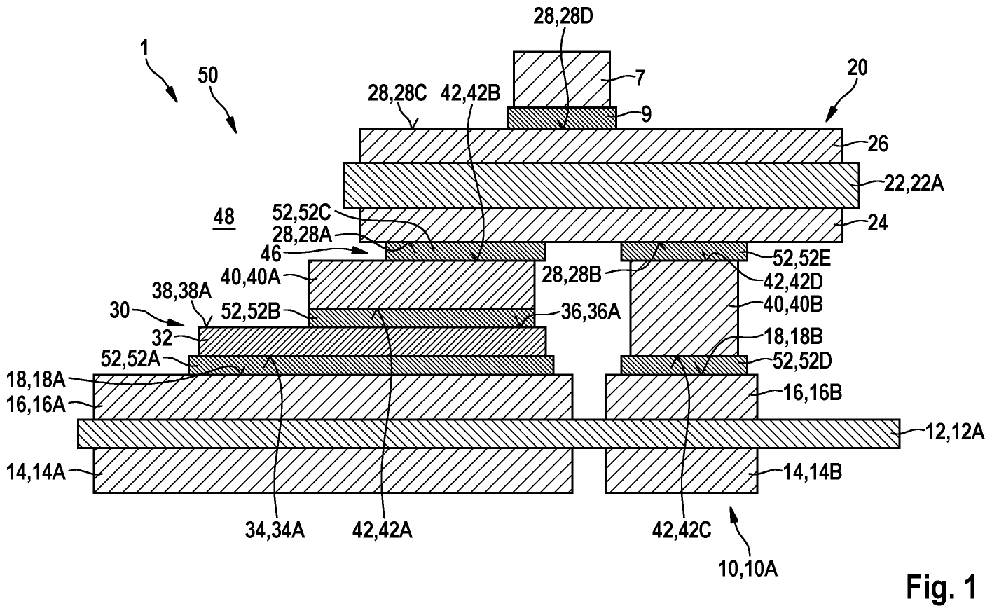

As can be seen in FIGS. 1 to 4, the illustrated exemplary embodiment of a power module 1 according to the present invention for a vehicle comprises a first circuit carrier 10, which has, on a first side, at least one power conductor structure 16 arranged on an electrically insulating layer 12. In addition, at least one further circuit carrier 20 is arranged spatially parallel to the first circuit carrier 10 and has, on a first side facing the first side of the first circuit carrier 10, at least one further power conductor structure 24 arranged on an electrically insulating layer 22. On a second side facing away from the first side of the first circuit carrier 10, the at least one second circuit carrier 20 has at least one control signal conductor structure 26 arranged on the electrically insulating layer 22. At least one semiconductor switch 30 has a semiconductor substrate 32 with two power terminals 34, 36 and at least one control terminal 38. In this case, the two power terminals 34, 36 of the at least one semiconductor switch 30 and at least one spacer element 40 are arranged between the at least one power conductor structure 16 of the first circuit carrier 10 and the at least one further power conductor structure 24 of the at least one further circuit carrier 20 in a stack 50 with at least three sinter layers 52. The at least one control terminal 38 of the semiconductor switch 30 is electrically connected via a connection line 44 to a corresponding contact region 28C of the at least one control signal conductor structure 26. The connection line is arranged in a free space and overlaps portions of the stack 50 and the at least one further circuit carrier 20.

As can further be seen in FIGS. 1 to 4, the illustrated detail of the power module 1 according to the present invention shows a detail of the first circuit carrier 10, which, in the illustrated exemplary embodiment, is designed as an AMB substrate (AMB: active metal brace). The second circuit carrier 20 is designed as a DBC substrate (DBC: direct bonded copper). The semiconductor switch 30 is designed as a field-effect transistor so that a drain contact surface 34A of the field-effect transistor corresponds to a first power terminal 34 of the semiconductor switch 30. A source contact surface 36A of the field-effect transistor corresponds to a second power terminal 36 of the semiconductor switch 30. A gate contact point 38A corresponds to the at least one control terminal 38 of the semiconductor switch 30. The first circuit carrier 10 comprises an electrically insulating layer 12 which is designed as a ceramic layer 12A and on the first side of which two power conductor structures 16A, 16B are formed in the illustrated detail. On a second side of the electrically insulating layer 12 or of the first circuit carrier 10 is arranged at least one conductor structure 14, which, in the illustrated detail, forms two thermal interfaces 14A, 14B that can be contacted with a cooling device. Furthermore, the illustrated detail of the power module 1 shows a further circuit carrier 20, which is arranged spatially parallel to the first circuit carrier 10 and has, on the first side, a further power conductor structure 24 arranged on the electrically insulating layer 22 designed as a ceramic layer 22A. On the second side, the second circuit carrier 20 has a control signal conductor structure 26 arranged on the electrically insulating layer 22.

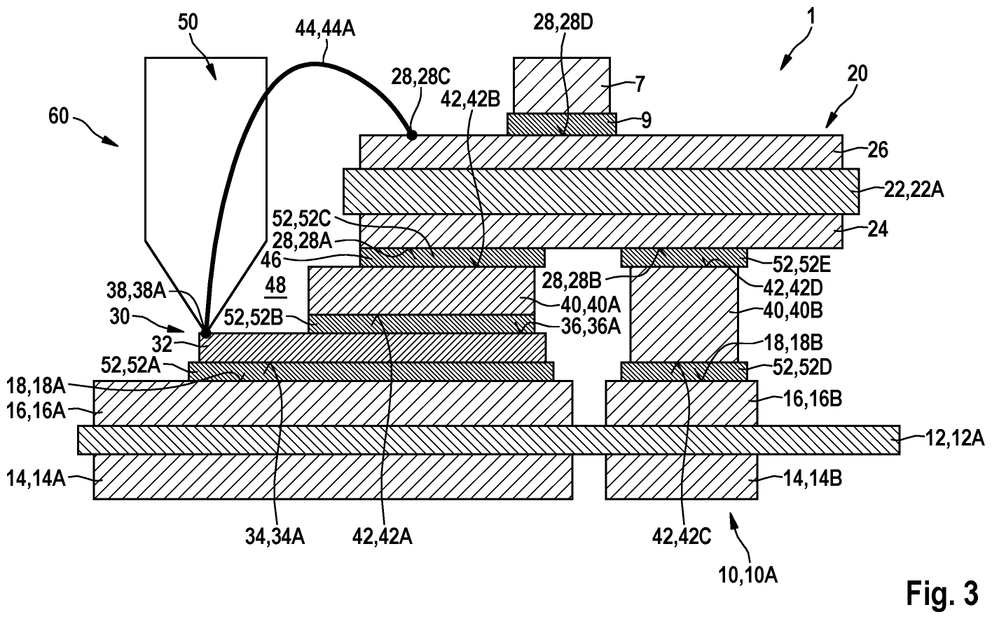

As can further be seen in FIGS. 1 to 4, the two power terminals 34, 36 of the illustrated semiconductor switch 30 and a first spacer element 40A are arranged between the first power conductor structure 16A of the first circuit carrier 10 and the further power conductor structure 24 of the further circuit carrier 20 in a first stack 50 with three sinter layers 52. In this case, the further circuit carrier 20 is arranged at an offset from the first spacer element 40A so that the free space 48 for the connection line 44 is formed. The control terminal 38 of the semiconductor switch 30 designed as a gate contact point 38A is electrically connected to a corresponding contact region 28C of the control signal conductor structure 26 via the connection line 44 designed as a bond wire 44A. As can further be seen in particular in FIG. 3, the free space 48 created by the offset of the further circuit carrier 20 enables the use of a bonding tool 60 to electrically connect the connection line 44, designed as a bond wire 44A, to the control terminal 38 of the semiconductor switch 30, designed as a gate contact point 38A, and to the corresponding contact region 28C of the control signal conductor structure 26.

As can further be seen in FIGS. 1 to 4, a first sinter layer 52A is formed between the first power conductor structure 16A of the first circuit carrier 10 and the power terminal 34 of the semiconductor switch 30 designed as a drain contact surface 34A. A second sinter layer 52B is formed between the power terminal 36 of the semiconductor switch 30, designed as a source contact surface 36A, and the first spacer element 40A. A third sinter layer 52C is formed between the first spacer element 40A and the further power conductor structure 24 of the further circuit carrier 20. In this case, at least one of the sinter layers 52 is applied as a sintering paste to the corresponding contact region 18, 42 of the first power conductor structure 16A or of the spacer element 40A or to the power terminal 36 of the semiconductor switch 30.

In the illustrated exemplary embodiment, the first sinter layer 52A between a first contact region 18A of the first power conductor structure 16A of the first circuit carrier 10 and the power terminal 34 of the semiconductor switch 30 designed as a drain contact surface 34A is applied as a sintering paste to the first contact region 18A of the first power conductor structure 16A. In this case, the first contact region 18A of the first power conductor structure 16A of the first circuit carrier 10 corresponds to at least one surface of the corresponding power terminal 34 of the semiconductor switch 30. As can further be seen in FIGS. 1 to 4, the first contact region 18A of the first power conductor structure 16A of the first circuit carrier 10 in the illustrated exemplary embodiment is formed to be larger than the drain contact surface 34A of the corresponding power terminal 34 of the semiconductor switch 30. The second sinter layer 52B between the power terminal 36 of the semiconductor switch 30, designed as a source contact surface 36A, and a first contact region 42A of the spacer element 42 is applied as a sinter foil to the power terminal 36 of the semiconductor switch 30 designed as a source contact surface 36A. In this case, the first contact region 42A of the first spacer element 40A corresponds to the source contact surface 36A of the corresponding power terminal 36 of the semiconductor switch 30. The third sinter layer 52C between a second contact region 42B of the spacer element 42 and a first contact region 28A of the further power conductor structure 24 of the second circuit carrier 20 is applied as a sintering paste to the second contact region 42B of the spacer element 42. In this case, the first contact region 28A of the further power conductor structure 24 of the further circuit carrier 10 at least partially covers the second contact region 42B of the first spacer element 40A. The covering of the second contact region 42B of the first spacer element 40A by the first contact region 28A of the further power conductor structure 24 of the further circuit carrier 10 is between 20% and 80%. In the illustrated exemplary embodiment, the covering corresponds to a value of approximately 778.

As can further be seen in FIGS. 1 to 4, a further spacer element 40B and two sinter layers 52 are arranged between the second power conductor structure 16B of the first circuit carrier 10 and the further power conductor structure 24 of the further circuit carrier 20. As can further be seen in FIGS. 1 to 4, a fourth sinter layer 52D is formed between the second power conductor structure 16B of the first circuit carrier 10 and the further spacer element 40B. A fifth sinter layer 52E is formed between the further spacer element 40B and the further power conductor structure 24 of the further circuit carrier 20.

In the illustrated exemplary embodiment, the fourth sinter layer 52D between a first contact region 18B of the second power conductor structure 16A of the first circuit carrier 10 and a first contact region 42C of the further spacer element 40B is applied as a sintering paste to the first contact region 18B of the second power conductor structure 16A. In this case, the first contact region 18B of the second power conductor structure 16B of the first circuit carrier 10 corresponds to at least one surface of the first contact region 42C of the further spacer element 40B. As can further be seen in FIGS. 1 to 4, the first contact region 18B of the second power conductor structure 16B of the first circuit carrier 10 in the illustrated exemplary embodiment is formed to be larger than the first contact region 42C of the further spacer element 40B. The fifth sinter layer 52E between the second contact region 42D of the further spacer element 42 and a second contact region 28B of the further power conductor structure 24 of the further circuit carrier 20 is applied as a sintering paste to the second contact region 42D of the further spacer element 40B. In this case, the second contact region 28B of the further power conductor structure 24 of the further circuit carrier 20 corresponds to at least one surface of the second contact region 42D of the further spacer element 40B. As can further be seen in FIGS. 1 to 4, the second contact region 28B of the further power conductor structure 24B of the further circuit carrier 20 in the illustrated exemplary embodiment is formed to be larger than the second contact region 42D of the further spacer element 40B.

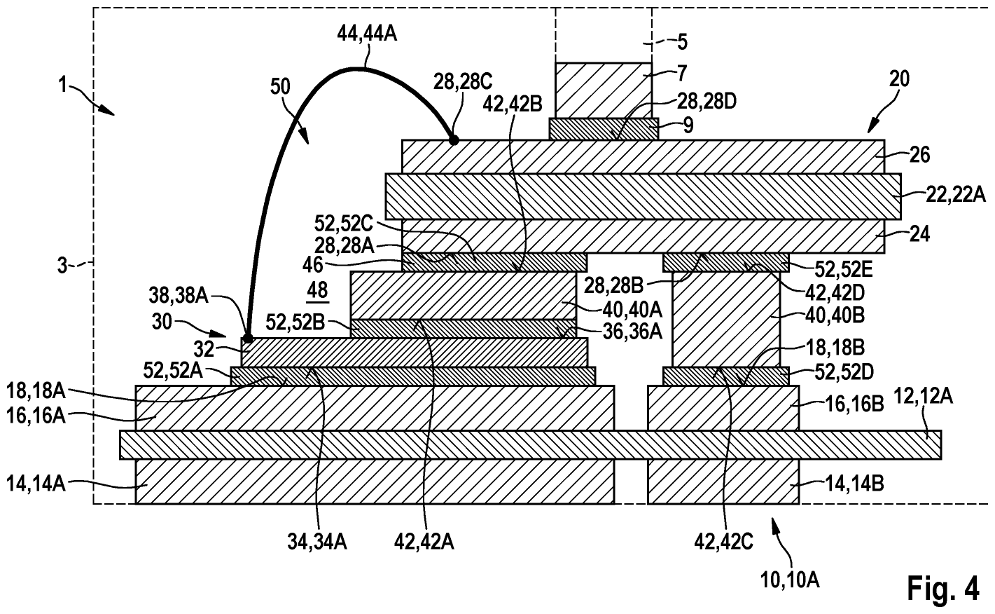

As can further be seen in FIG. 4, the finished power module 1 has a casing 3 (shown in dashed lines), which completely surrounds the power module 1 while leaving the at least one thermal interface 14A, 14B exposed. The casing 3 has at least one recess 5 in the region of at least one external contact terminal 7. In the illustrated detail of the power module 1, an external contact terminal 7 is electrically connected via a conductive adhesive layer 9 to a corresponding contact region 28D of the control signal conductor structure 26.

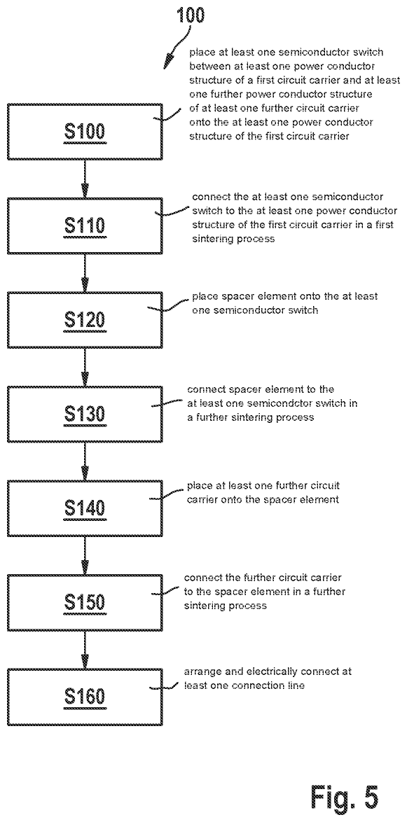

As can further be seen in FIG. 5, the illustrated exemplary embodiment of a method 100 according to the present invention for constructing an above-described power module 1 for a vehicle comprises a step S100. In step S100, in order to form a stack 50 with at least three sinter layers 52, at least one semiconductor switch 30, which has a semiconductor substrate 32 with two power terminals 34, 36 and at least one control terminal 38, is placed between at least one power conductor structure 16 of a first circuit carrier 10 and at least one further power conductor structure 24 of at least one further circuit carrier 20 onto the at least one power conductor structure 16 of the first circuit carrier 10 and is connected in a step S110 to the at least one power conductor structure 16 of the first circuit carrier 10 in a first sintering process. In a step S120, at least one spacer element 40 is placed onto the at least one semiconductor switch 30 and is connected in a step S130 to the at least one semiconductor switch 30 in at least one further sintering process. In a step S140, the at least one further circuit carrier 20 is placed onto the at least one spacer element 40 and is connected in a step S150 to the spacer element 40 via a further sintering process. In a step S160, at least one connection line 44 is arranged in a free space 48 and is electrically connected to the at least one control terminal 38 of the semiconductor switch 30 and to a corresponding contact region 28C of at least one control signal conductor structure 26 of the at least one further circuit carrier 20 such that portions of the stack 50 and the at least one further circuit carrier 20 are overlapped by the at least one connection line 44.

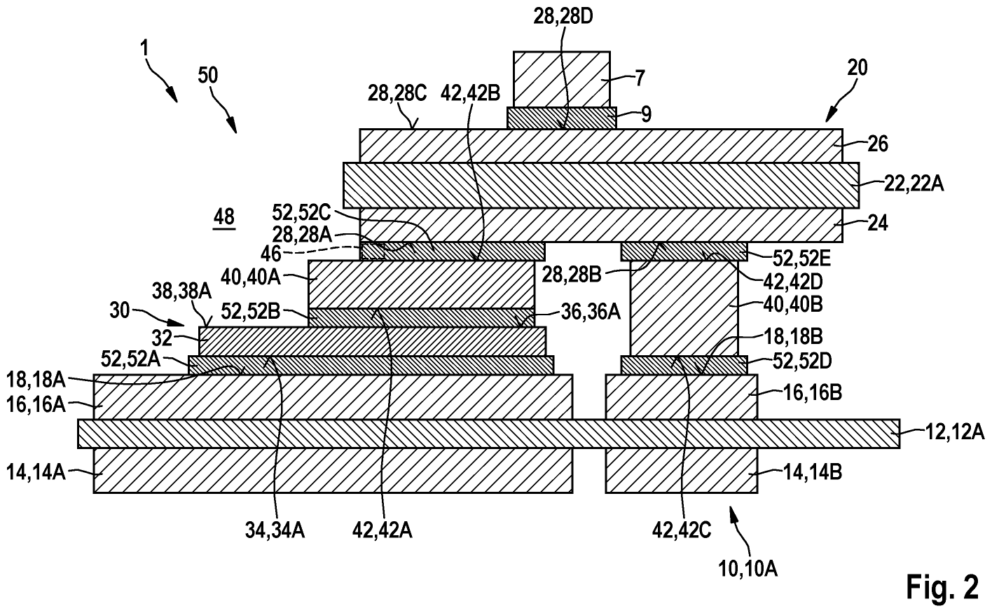

As can further be seen in FIG. 1, in step S140, before the further circuit carrier 20 is placed, a sinter layer 52C is applied as a sintering paste between the first spacer element 40A and the further power conductor structure 24 of the further circuit carrier 20 onto the corresponding second contact region 42B of the first spacer element 40A for the third sintering process in step S150. In step S140, the further circuit carrier 20 is placed at such an offset from the first spacer element 40A that an undercut 46 is formed between the first spacer element 40A and the further power conductor structure 24 of the further circuit carrier 20. In addition, the placed further circuit carrier 20 is pressed with a specified force in the range of 1.5 g/mm² to 2.5 g/mm² onto the sintering paste so that the corresponding third sinter layer 52C fills up the undercut 46 before the third sintering process in step S150, as can be seen in FIG. 2. After the third sintering process in step S150, the connection line 44 designed as a bond wire 44A is electrically connected in step S160 by means of a bonding tool 60 to the control terminal 38 of the semiconductor switch 30, designed as a gate contact point 38A, and to the corresponding contact region 28C of the control signal conductor structure 26, as can be seen in FIG. 3. The power module 1 is subsequently encased with a mold compound so that the casing 3 shown in dashed lines in FIG. 4 is formed.

1-15. (canceled)

16. A power module for a vehicle, comprising:
a first circuit carrier, which has, on a first side, at least one power conductor structure arranged on an electrically insulating layer;
at least one further circuit carrier, which is arranged spatially parallel to the first circuit carrier and has, on a first side facing the first side of the first circuit carrier, at least one further power conductor structure arranged on an electrically insulating layer, and, on a second side facing away from the first side of the first circuit carrier, at least one control signal conductor structure arranged on the electrically insulating layer; and
at least one semiconductor switch, which has a semiconductor substrate with two power terminals and at least one control terminal, wherein the two power terminals of the at least one semiconductor switch and at least one spacer element are arranged between the at least one power conductor structure of the first circuit carrier and the at least one further power conductor structure of the at least one further circuit carrier in a stack with at least three sinter layers, wherein the at least one control terminal of the semiconductor switch is electrically connected via a connection line to a corresponding contact region of the at least one control signal conductor structure, and wherein the connection line is arranged in a free space and overlaps portions of the stack and the at least one further circuit carrier.

17. The power module according to claim 16, wherein the at least one further circuit carrier is arranged at an offset from the at least one spacer element so that the free space for the connection line is formed.

18. The power module according to claim 16, wherein a first sinter layer of the at least three sinter layers is formed between the at least one power conductor structure of the first circuit carrier and one of the two power terminals of the at least one semiconductor switch, wherein a second sinter layer of the at least three sinter layers is formed between the other of the two power terminals of the at least one semiconductor switch and the at least one spacer element, and wherein a third sinter layer of the at least three sinter layers is formed between the at least one spacer element and the at least one further power conductor structure of the at least one further circuit carrier.

19. The power module according to claim 18, wherein at least one of the at least three sinter layers is applied as a sintering paste to a corresponding contact region or the other of the two power terminals.

20. The power module according to claim 18, wherein the first sinter layer and the third sinter layer are each applied as a sintering paste.

21. The power module according to claim 18, wherein the second sinter layer is applied as a sinter foil.

22. The power module according to claim 18, wherein a first contact region of the at least one power conductor structure of the first circuit carrier corresponds to at least one surface of the one of the two power terminals of the at least one semiconductor switch.

23. The power module according to claim 16, wherein a first contact region of the at least one spacer element corresponds to a surface of the other of the two power terminals of the at least one semiconductor switch.

24. The power module according to claim 18, wherein a first contact region of the at least one further power conductor structure of the at least one further circuit carrier at least partially covers a second contact region of the at least one spacer element.

25. The power module according to claim 24, wherein the first contact region of the at least one further power conductor structure of the at least one further circuit carrier covers 20% to 80% of the second contact region of the at least one spacer element.

26. The power module according to claim 16, wherein the first circuit carrier has, on a second side, at least one conductor structure, which forms at least one thermal interface that can be contacted with a cooling device.

27. The power module according to claim 26, wherein a casing completely surrounds the power module while leaving the at least one thermal interface exposed, wherein the casing has at least one recess in the region of at least one external contact terminal.

28. A method for constructing a power module for a vehicle, the method comprising the following steps:
forming a stack with at least three sinter layers, placing at least one semiconductor switch, which has a semiconductor substrate with two power terminals and at least one control terminal between at least one power conductor structure of a first circuit carrier and at least one further power conductor structure of at least one further circuit carrier onto the at least one power conductor structure of the first circuit carrier and connecting the at least one semiconductor switch to the at least one power conductor structure of the first circuit carrier in a first sintering process;
placing at least one spacer element onto the at least one semiconductor switch and connecting the at least one spacer element to the at least one semiconductor switch in at least one further sintering process;
placing the at least one further circuit carrier onto the at least one spacer element and connecting the at least one further circuit carrier to the spacer element via a third sintering process; and
arranging at least one connection line in a free space and electrically connecting the at least one connection line to at least one control terminal of the semiconductor switch and to a corresponding contact region of at least one control signal conductor structure of the at least one further circuit carrier such that portions of the stack and the at least one further circuit carrier are overlapped by the at least one connection line.

29. The method according to claim 28, wherein a sinter layer between the at least one spacer element and the at least one further power conductor structure of the at least one further circuit carrier is applied as a sintering paste only to a portion of a contact region of the at least one spacer element for the third sintering process, wherein the at least one further circuit carrier is placed at such an offset from the at least one spacer element that an undercut is formed between the at least one spacer element and the at least one further power conductor structure of the at least one further circuit carrier.

30. The method according to claim 29, wherein the at least one further circuit carrier is pressed onto the sintering paste with a specified force in a range of 1.5 g/mm² to 2.5 g/mm² so that a corresponding sinter layer fills up the undercut before the third sintering process.
